(19) United States
(12) Patent Application Publication
(10) Pub. No.: US 2026/0367535 A1
(43) Pub. Date: Nov. 19, 2026

(54) A CLAMP AND A METHOD FOR MANUFACTURING THE SAME

(71) Applicant: ASML NETHERLANDS B.V., Veldhoven (NL)

(72) Inventors: Michael Andrew CHIEDA, Easton, CT (US); Matthew LIPSON, Stamford, CT (US); Moshe SHEMESH, Fairfield, CT (US)

(73) Assignee: ASML NETHERLANDS B.V., Veldhoven (NL)

(21) Appl. No.: 19/135,772

(22) PCT Filed: Nov. 14, 2023
(86) PCT No.: PCT/EP2023/081766

§ 371 Date: Jun. 4, 2025

Related U.S. Application Data
(60) Provisional application No. 63/432,112, filed on Dec. 13, 2022.

(51) Int. Cl. G03F 7/00

(52) U.S. Cl. CPC G03F 7/70875; G03F 7/70708

(57) ABSTRACT

A method includes bonding a first layer and a second layer of a clamp by heating the first layer and the second layer up to a holding temperature of a least 700 °C, maintaining the first layer and the second layer at the holding temperature during a holding time period, and cooling down the first layer and the second layer after the holding time has elapsed at a cooling rate of a maximum of 20 °C/hour for a cooling time period.

### CROSS-REFERENCE TO RELATED APPLICATION

This application claims priority of U.S. application 63/432,112 which was filed on 13 December 2022, and which is incorporated herein in its entirety by reference.

### TECHNICAL FIELD

The present disclosure relates to a clamp for supporting an object, for example, a patterning device and/or a substrate in a lithographic apparatus, and a method for manufacturing the same.

### BACKGROUND

A lithographic apparatus is a machine that applies a desired pattern onto a target portion of a substrate. Lithographic apparatus can be used, for example, in the manufacture of integrated circuits (ICs). In that circumstance, a patterning device, which is alternatively referred to as a mask or a reticle, may be used to generate a circuit pattern corresponding to an individual layer of the IC, and this pattern can be imaged onto a target portion (e.g., comprising part of, one or several dies) on a substrate (e.g., a silicon wafer) that has a layer of radiation-sensitive material (resist). In general, a single substrate will contain a network of adjacent target portions that are successively exposed. Known lithographic apparatus include so-called steppers, in which each target portion is irradiated by exposing an entire pattern onto the target portion in one go, and so-called scanners, in which each target portion is irradiated by scanning the pattern through the beam in a given direction (the “scanning”-direction) while synchronously scanning the substrate parallel or anti parallel to this direction. It is also possible to transfer the pattern from the patterning device to the substrate by imprinting the pattern onto the substrate.

Lithography is widely recognized as one of the key steps in the manufacture of ICs and other devices and/or structures. However, as the dimensions of features made using lithography become smaller, lithography is becoming a more critical factor for enabling miniature IC or other devices and/or structures to be manufactured.

A theoretical estimate of the limits of pattern printing can be given by the Rayleigh criterion for resolution as shown in equation (1):

$$CD = {k}_{1} * \frac{λ}{NA} \qquad ( 1 )$$

where λ is the wavelength of the radiation used, NA is the numerical aperture of the projection system used to print the pattern, k₁ is a process dependent adjustment factor, also called the Rayleigh constant, and CD is the feature size (or critical dimension) of the printed feature. It follows from equation (1) that reduction of the minimum printable size of features can be obtained in three ways: by shortening the exposure wavelength λ, by increasing the numerical aperture NA, or by decreasing the value of k₁.

In order to shorten the exposure wavelength, and thus, reduce the minimum printable size, it has been proposed to use an extreme ultraviolet (EUV) radiation source. EUV radiation is electromagnetic radiation having a wavelength within the range of 5-20 nm, for example within the range of 13-14 nm, for example within the range of 5-10 nm such as 6.7 nm or 6.8 nm. Possible sources include, for example, laser-produced plasma sources, discharge plasma sources, or sources based on synchrotron radiation provided by an electron storage ring.

The radiation generated by such sources will not, however, be only EUV radiation and the source may also emit at other wavelengths including infra-red (IR) radiation and deep ultra-violet (DUV) radiation. DUV radiation can be detrimental to the lithography system as it can result in a loss of contrast. Furthermore unwanted IR radiation can cause heat damage to components within the system. It is therefore known to use a spectral purity filter to increase the proportion of EUV in the transmitted radiation and to reduce or even eliminate unwanted non-EUV radiation such as DUV and IR radiation.

A lithographic apparatus using EUV radiation may require that the EUV radiation beam path, or at least substantial parts of it, must be kept in vacuum during a lithographic operation. In such vacuum regions of the lithographic apparatus, an electrostatic clamp may be used to clamp an object, such as a patterning device and/or a substrate to a structure of the lithographic apparatus, such as a patterning device table and/or a substrate table, respectively.

In addition, a lithographic apparatus using EUV radiation may require temperature regulation of, for example, the patterning device and/or the substrate. Heat produced by the EUV radiation or the unwanted non-EUV radiation may cause deformations in, for example, the patterning device and/or the substrate during a lithographic operation because of the heat absorbed by the patterning device and/or the substrate. To reduce the deformation, a coolant may be circulated through the electrostatic clamp. However, configuring an electrostatic clamp for circulating a coolant can create stress in the clamp structure. This stress may be transferred to the object (e.g., patterning device, substrate) clamped to the electrostatic clamp, resulting in deformations in the clamped object.

### SUMMARY

Accordingly, there is a need for an electrostatic clamp that can be configured to securely hold an object and prevent heat-induced and stress-induced deformation in the clamped object.

According to an embodiment, a method is provided. The method includes bonding a first layer and a second layer of a clamp by heating the first layer and the second layer up to a holding temperature of a least 700 °C, maintaining the first layer and the second layer at the holding temperature during a holding time period, and cooling down the first layer and the second layer after the holding time has elapsed at a cooling rate of a maximum of 20 °C/hour for a cooling time period.

In another embodiment, a lithographic apparatus is provided. The lithographic apparatus includes a chuck, and an electrostatic clamp, coupled to the chuck, configured to releasably hold a patterning device. The electrostatic clamp includes a first layer and a second layer. The first layer and the second layer are bonded together using a heat treatment. The heat treatment comprises heating the first layer and the second layer up to a holding temperature of a least 700 °C, maintaining the first layer and the second layer at the holding temperature during a holding time period, and cooling down the first layer and the second layer after the holding time period has elapsed at a cooling rate of a maximum of 20 °C/hour for a cooling time period.

Yet in another embodiment, a clamp is provided. The clamp may include a first layer and a second layer. The first layer and the second layer are bonded together using a heat treatment. The heat treatment includes heating the first layer and the second layer up to a holding temperature of a least 700 °C, maintaining the first layer and the second layer at the holding temperature during a holding time period, and cooling down the first layer and the second layer after the holding time has elapsed at a cooling rate of a maximum of 20 °C/hour for a cooling time period.

Further features of the present disclosure, as well as the structure and operation of various embodiments, are described in detail below with reference to the accompanying drawings. It is noted that the present disclosure is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the present disclosure and to enable a person skilled in the relevant art(s) to make and use embodiments described herein.

FIG. 1A shows a schematic of a reflective lithographic apparatus, according to some aspects of the present disclosure.

FIG. 1B shows a schematic of a transmissive lithographic apparatus, according to some aspects of the present disclosure.

FIG. 2 shows a more detailed schematic illustration of the reflective lithographic apparatus, according to some aspects of the present disclosure.

FIG. 3 shows a schematic of a lithographic cell, according to some aspects of the present disclosure.

FIG. 4 is a schematic illustration of a cross-sectional view of an electrostatic clamp, according to some aspects of the present disclosure.

FIG. 5 is a schematic illustration of a cross-sectional view of an electrostatic clamp and a chuck, according to some aspects of the present disclosure.

FIGS. 6A-N are schematic illustrations of cross-sectional views of an electrostatic clamp at select stages of its manufacturing process, according to some aspects of the present disclosure.

FIG. 7 is a schematic illustration of a cross-sectional view of an electrostatic clamp during coupling with a chuck, according to some aspects of the present disclosure.

FIG. 8 is a flowchart for a manufacturing process of an electrostatic clamp, according to some aspects of the present disclosure.

FIG. 9 is a flowchart for a bonding method, according to some aspects of the present disclosure.

FIG. 10 is a schematic that shows a computer system, according to some aspects of the present disclosure.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of the present disclosure. The disclosed embodiment(s) are provided as examples. The scope of the present disclosure is not limited to the disclosed embodiment(s). Claimed features are defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

The term “about” as used herein indicates the value of a given quantity that can vary based on a particular technology. Based on the particular technology, the term “about” can indicate a value of a given quantity that varies within, for example, 10-30% of the value (e.g., +10%, +20%, or +30% of the value).

Embodiments of the disclosure can be implemented in hardware, firmware, software, or any combination thereof. Embodiments of the disclosure may also be implemented as instructions stored on a machine-readable medium, which can be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions can be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present disclosure may be implemented.

### Example Lithographic Systems

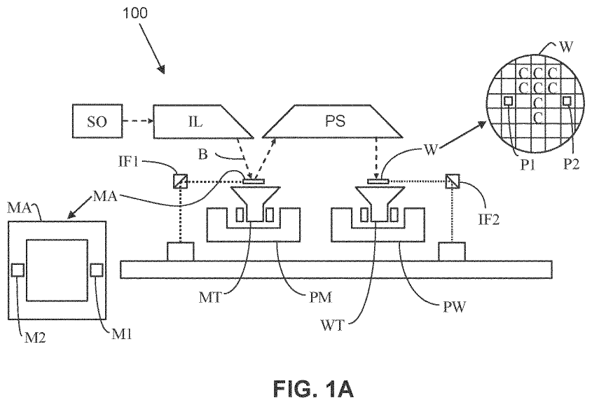

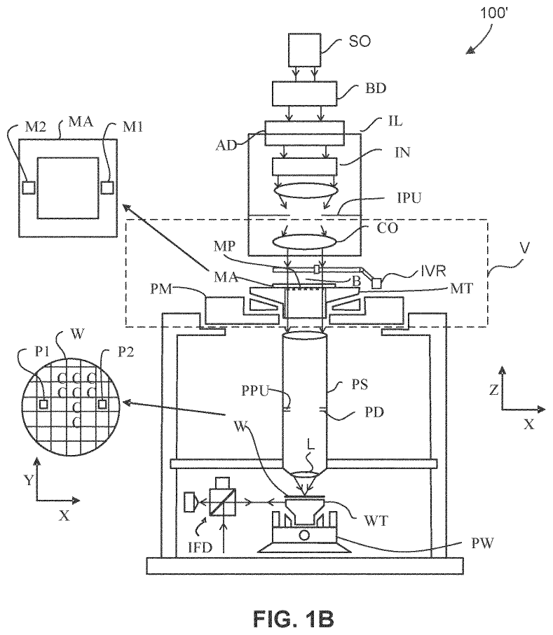

FIGS. 1A and 1B show schematic illustrations of a lithographic apparatus 100 and lithographic apparatus 100′, respectively, in which embodiments of the present disclosure may be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL may include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT may use mechanical, vacuum, electrostatic, or other clamping techniques to hold the patterning device MA. The support structure MT may be a frame or a table, for example, which may be fixed or movable, as required. By using sensors, the support structure MT may ensure that the patterning device MA is at a desired position, for example, with respect to the projection system PS.

The term “patterning device” MA should be broadly interpreted as referring to any device that may be used to impart a radiation beam B with a pattern in its cross-section, such as to create a pattern in the target portion C of the substrate W. The pattern imparted to the radiation beam B may correspond to a particular functional layer in a device being created in the target portion C to form an integrated circuit.

The terms “inspection apparatus,” “metrology system,” or the like may be used herein to refer to, e.g., a device or system used for measuring a property of a structure (e.g., overlay error, critical dimension parameters) or used in a lithographic apparatus to inspect an alignment of a wafer (e.g., alignment apparatus).

The patterning device MA may be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which may be individually tilted so as to reflect an incoming radiation beam in different directions. The tilted mirrors impart a pattern in the radiation beam B, which is reflected by a matrix of small mirrors.

The term “projection system” PS may encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment may be used for EUV or electron beam radiation since other gases may absorb too much radiation or electrons. A vacuum environment may therefore be provided to the whole beam path with the aid of a vacuum wall and vacuum pumps.

Lithographic apparatus 100 and/or lithographic apparatus 100′ may be of a type having two (dual stage) or more substrate tables WT (and/or two or more mask tables). In such “multiple stage” machines, the additional substrate tables WT may be used in parallel, or preparatory steps may be carried out on one or more tables while one or more other substrate tables WT are being used for exposure. In some situations, the additional table may not be a substrate table WT.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIGS. 1A and 1B, the illuminator IL receives a radiation beam from a radiation source SO. The source SO and the lithographic apparatus 100, 100′ may be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO may be an integral part of the lithographic apparatus 100, 100′, for example, when the source SO is a mercury lamp. The source SO and the illuminator IL, together with the beam delivery system BD, if required, may be referred to as a radiation system.

The illuminator IL may include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator may be adjusted. In addition, the illuminator IL may comprise various other components (in FIG. 1B), such as an integrator IN and a condenser CO. The illuminator IL may be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT may be moved accurately (for example, so as to position different target portions C in the path of the radiation beam B). Similarly, the first positioner PM and another position sensor IF1 may be used to accurately position the patterning device (for example, mask) MA with respect to the path of the radiation beam B. Patterning device (for example, mask) MA and substrate W may be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image of the mask pattern MP, where the image is formed by diffracted beams produced from the mark pattern MP by radiation from the intensity distribution, onto a photoresist layer coated on the substrate W. For example, the mask pattern MP may include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture, by means of a lens or lens group L, not only the zeroth order diffracted beams, but also first-order or first- and higher-order diffracted beams (not shown). In some embodiments, dipole illumination for imaging line patterns extending in a direction perpendicular to a line may be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some embodiments, astigmatism aberration may be reduced by providing radiation poles (not shown) in opposite quadrants of the illumination system pupil IPU. Further, in some embodiments, astigmatism aberration may be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IFD (for example, an interferometric device, linear encoder, or capacitive sensor), the substrate table WT may be moved accurately (for example, so as to position different target portions C in the path of the radiation beam B). Similarly, the first positioner PM and another position sensor (not shown in FIG. 1B) may be used to accurately position the mask MA with respect to the path of the radiation beam B (for example, after mechanical retrieval from a mask library or during a scan).

In general, movement of the mask table MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the mask table MT may be connected to a short-stroke actuator only or may be fixed. Mask MA and substrate W may be aligned using mask alignment marks M1, M2, and substrate alignment marks P1, P2. Although the substrate alignment marks (as illustrated) occupy dedicated target portions, they may be located in spaces between target portions (known as scribe-lane alignment marks). Similarly, in situations in which more than one die is provided on the mask MA, the mask alignment marks may be located between the dies.

Mask table MT and patterning device MA may be in a vacuum chamber V, where an in-vacuum robot IVR may be used to move patterning devices such as a mask in and out of vacuum chamber. Alternatively, when mask table MT and patterning device MA are outside of the vacuum chamber, an out-of-vacuum robot may be used for various transportation operations, similar to the in-vacuum robot IVR. Both the in-vacuum and out-of-vacuum robots need to be calibrated for a smooth transfer of any payload (e.g., mask) to a fixed kinematic mount of a transfer station.

The lithographic apparatus 100 and 100′ may be used in at least one of the following modes:

1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C may be exposed.

2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT may be determined by the (de-) magnification and image reversal characteristics of the projection system PS.

3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO may be employed and the programmable patterning device is updated as required after each movement of the substrate table WT or in between successive radiation pulses during a scan. This mode of operation may be readily applied to maskless lithography that utilizes a programmable patterning device, such as a programmable mirror array.

Combinations and/or variations on the described modes of use or entirely different modes of use may also be employed.

In a further embodiment, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

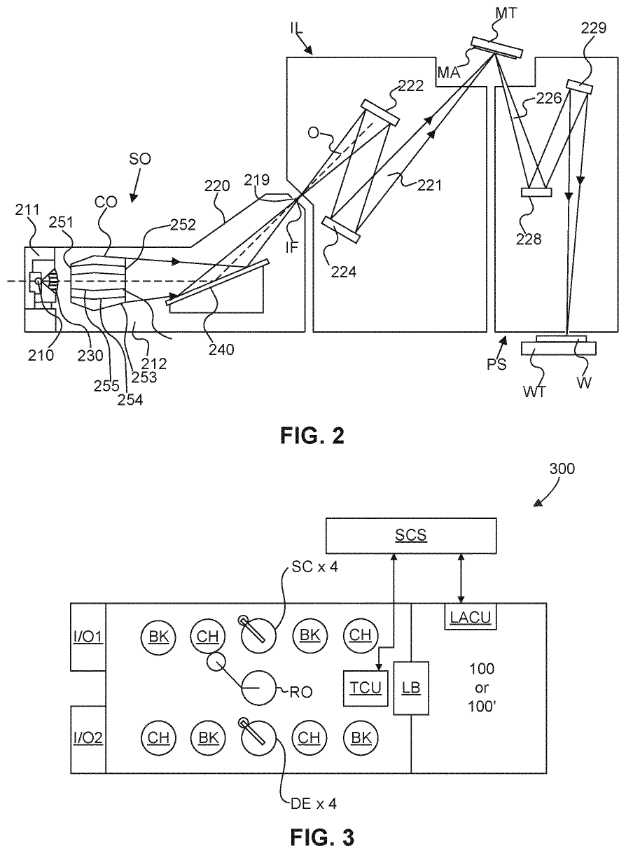

FIG. 2 shows the lithographic apparatus 100 in more detail, including the source collector apparatus SO, the illumination system IL, and the projection system PS. The source collector apparatus SO is constructed and arranged such that a vacuum environment may be maintained in an enclosing structure 220 of the source collector apparatus SO. An EUV radiation emitting plasma 210 may be formed by a discharge produced plasma source. EUV radiation may be produced by a gas or vapor, for example Xe gas, Li vapor, or Sn vapor in which the very hot plasma 210 is created to emit radiation in the EUV range of the electromagnetic spectrum. The very hot plasma 210 is created by, for example, an electrical discharge causing at least a partially ionized plasma. Partial pressures of, for example, 10 Pa of Xe, Li, Sn vapor, or any other suitable gas or vapor may be required for efficient generation of the radiation. In some embodiments, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap), which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure.

The collector chamber 212 may include a radiation collector CO, which may be a so-called grazing incidence collector. Radiation collector CO has an upstream radiation collector side 251 and a downstream radiation collector side 252. Radiation that traverses collector CO may be reflected off a grating spectral filter 240 to be focused in a virtual source point INTF. The virtual source point INTF is commonly referred to as the intermediate focus, and the source collector apparatus is arranged such that the intermediate focus INTF is located at or near an opening 219 in the enclosing structure 220. The virtual source point INTF is an image of the radiation emitting plasma 210. Grating spectral filter 240 is used in particular for suppressing infra-red (IR) radiation.

Subsequently the radiation traverses the illumination system IL, which may include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the beam of radiation 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown may generally be present in illumination optics unit IL and projection system PS. The grating spectral filter 240 may optionally be present, depending upon the type of lithographic apparatus. Further, there may be more mirrors present than those shown in the FIG. 2, for example there may be one to six additional reflective elements present in the projection system PS than shown in FIG. 2.

Collector optic CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a collector optic CO of this type is preferably used in combination with a discharge produced plasma source, often called a DPP source.

### Exemplary Lithographic Cell

FIG. 3 shows a lithographic cell 300, also sometimes referred to a lithocell or cluster, according to some embodiments. Lithographic apparatus 100 or 100′ may form part of lithographic cell 300. Lithographic cell 300 may also include one or more apparatuses to perform pre- and post-exposure processes on a substrate. Conventionally these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses may be operated to maximize throughput and processing efficiency.

### Example Embodiments of Electrostatic Clamp

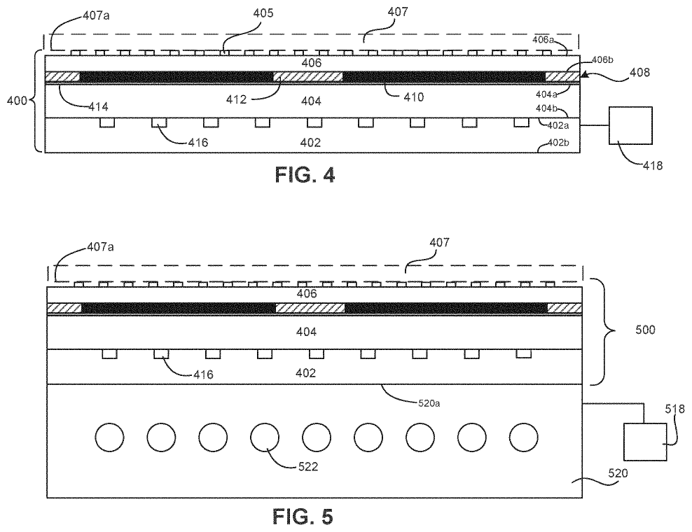

FIG. 4 shows a schematic of a cross-sectional view of an electrostatic clamp 400 that may be implemented as a part of lithographic apparatus 100, according to an embodiment. In an example of this embodiment, electrostatic clamp 400 may be used for holding substrate W on substrate table WT or patterning device MA on support structure MT in lithographic apparatus 100.

According to an embodiment, electrostatic clamp 400 may comprise a multi-layered structure including a first layer 402 having opposing and parallel surfaces 402a and 402b, a second layer 404 having opposing and parallel surfaces 404a and 404b, and a third layer 406 having opposing and parallel surfaces 406a and 406b. First layer 402, second layer 404, and third layer 406 may have vertical dimensions in the range of about 1-4 mm, 1-4 mm, and 50-200 microns, respectively, according to an example of this embodiment. First layer 402 may be coupled to second layer 404 with surface 402a being in substantial contact with surface 404b and third layer 406 may be coupled to second layer 404 with surface 404a facing surface 406b. Surface 406a of third layer 406 may define a clamping surface 406a of electrostatic clamp 400. Clamping surface 406a may be configured to receive an object 407 (e.g., substrate W or patterning device MA) to be clamped to electrostatic clamp 400. Object 407 may be clamped to be in substantial contact with clamping surface 406a. Optionally, clamping surface 406a may include burls 405 configured to be in contact with object 407 during clamping operation. Burls 405 may help to provide less contaminated contact between object 407 and clamping surface 406a as contaminants are less likely to be on the smaller surface area of burls 405 than the larger surface area of clamping surface 406a.

In an embodiment, first layer 402, second layer 404, and third layer 406 may comprise materials different from each other. In another embodiment, first layer 402, second layer 404, and third layer 406 may be manufactured out of one or more dielectric materials configured to support an electrostatic field during operation of electrostatic clamp 400, as further explained in below. The dielectric materials may have ultra-low thermal expansion coefficients that may be equal to zero or substantially zero, such as, but not limited to, an ultra-low expansion silicon-based material (e.g., ULE® manufactured by Corning), a glass material, a ceramic material, a silicon-based glass ceramic material (e.g., ZERODUR® manufactured by SCHOTT), or a combination thereof. Any of these ultra-low expansion thermal materials may help to reduce thermal stress in the structure of electrostatic clamp 400 during its manufacture. Thermal stress in electrostatic clamp 400 if not reduced may result in one or more unwanted deformations in first layer 402, second layer 404, and/or third layer 406, which may be transferred to object 407 during clamping operation.

In another embodiment, first layer 402 and/or second layer 404 may be manufactured out of one or more non-dielectric insulating materials having ultra-low thermal expansion coefficients.

Yet in another embodiment, first layer 402, second layer 404, and third layer 406 may be manufactured out of the same one or more ultra-low thermal expansion dielectric materials. Manufacturing all three layers of electrostatic clamp 400 from similar materials may help to further reduce thermal stress due to thermal expansion mismatch between dissimilar materials. In an example of this embodiment, first layer 402, second layer 404, and third layer 406 may be manufactured out of the ULE® material, which provides higher electrical stability than the ZERODUR® material.

As illustrated in FIG. 4, electrostatic clamp 400 further comprises a composite layer 408 interposed between second layer 404 and third layer 406, according to an embodiment. In an example of this embodiment, composite layer 408 may have a vertical dimension in the range of about 50-400 nm. Composite layer 408 includes electrically conductive regions 410 and insulating regions 412 (also referred to herein as layers) that are arranged in an alternating configuration. One of electrically conductive regions 410 is electrically isolated from the other by one of insulating regions 412. Although FIG. 4 illustrates only two electrically conductive regions, it is to be understood that in other modifications of the disclosure composite layer 408 may include a single or more than two electrically conductive layers. In an embodiment, electrically conductive regions 410 and insulating regions 412 are coplanar.

In various examples of this embodiment, any suitable electrically conductive material such as, but not limited to, aluminum, chrome, platinum, gold, or a combination thereof, may be used to form electrically conductive regions 410 and any suitable insulating material such as, silicon oxide or other insulating metal oxides may be used to form insulating regions 412. In another example, electrically conductive regions 410 may comprise a single layer of metal, multiple layers of a same metal, or multiple layers of different metals.

Electrically conductive regions 410 may be configured as electrodes 410 to generate an electrostatic field within third layer 406 for clamping object 407 to clamping surface 406a, according to an example embodiment. The electrostatic field may be generated by providing a clamping voltage to electrodes 410. The clamping voltage may induce surface image charges on a conductive surface 407a of object 407 to electrostatically attract and clamp object 407 to clamping surface 406a.

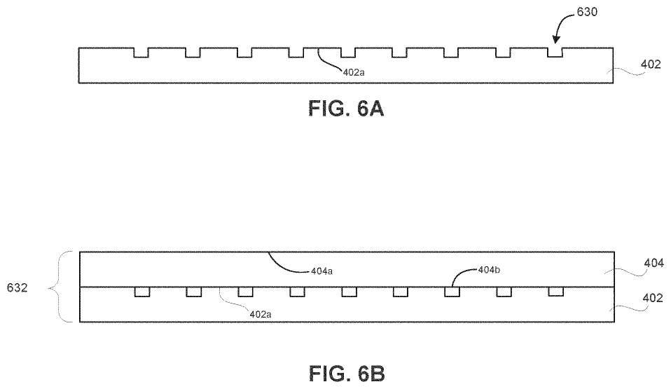

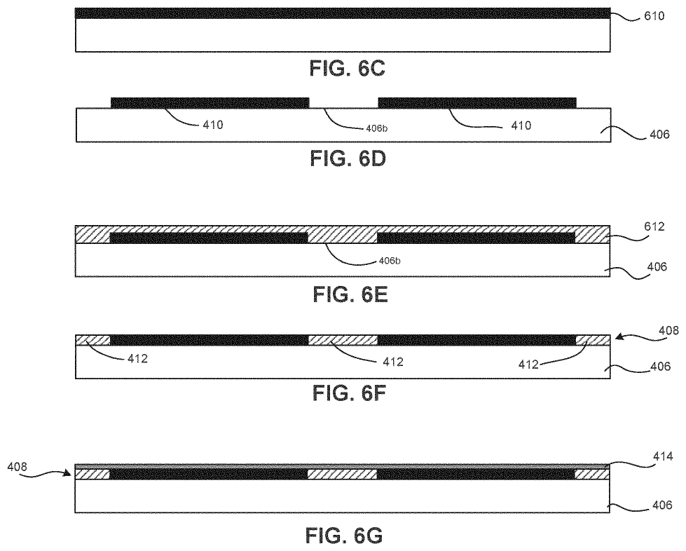

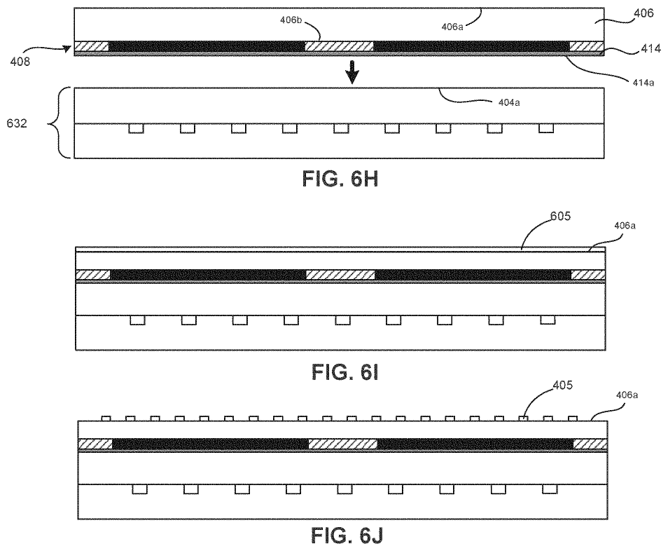

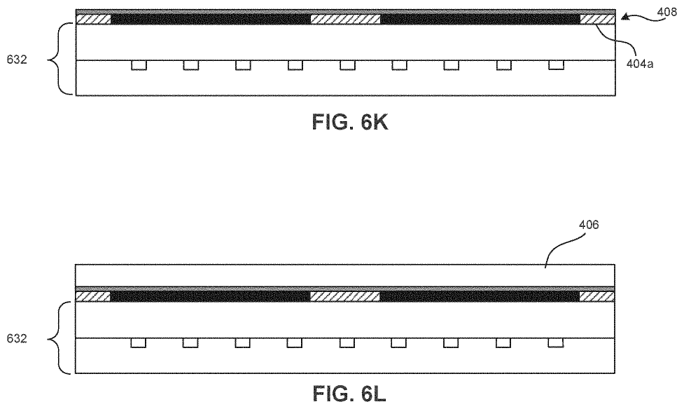

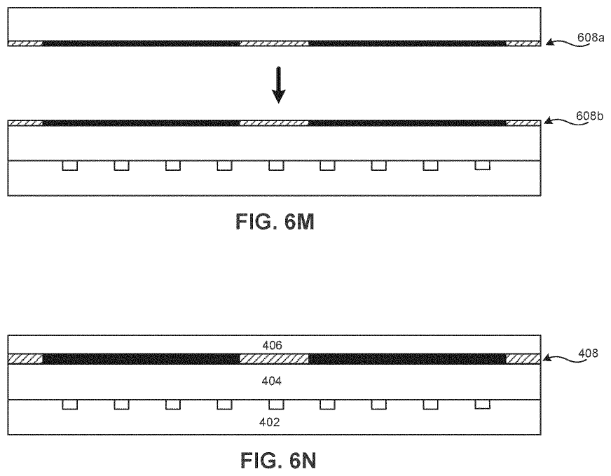

Electrostatic clamp 400 may optionally comprise an intermediate layer 414 interposed between composite layer 408 and second layer 404, as illustrated in FIG. 4, according to an embodiment. Intermediate layer 414 may comprise a silicon-based material, such as silicon oxide or aluminum oxide, and may be configured as a bonding medium for bonding composite layer 414 to second layer 404. In an example of this embodiment, intermediate layer 414 may have a vertical dimension of about 10-200 nm. Alternatively, intermediate layer 414 may be interposed between composite layer 408 and third layer 406, as discussed in further details below with reference to FIGS. 6J-K.

In a further embodiment, electrostatic clamp 400 comprises fluid channels 416, as illustrated in FIG. 4. Fluid channels 416 may be configured to run parallel to surface 402a and carry a thermally conditioned fluid (e.g., liquids or gas), such as, but not limited to water, air, alcohols, glycols, or phase change coolants (e.g., Freons, carbon dioxide). A fluid conditioning system 418 coupled to electrostatic clamp 400 may be configured to condition the thermally conditioned fluid to a desired temperature before entering fluid channels 416 and to circulate it through electrostatic clamp 400. The circulating thermally conditioned fluid may help to regulate temperature of electrostatic clamp 400 to a desired temperature. Temperature regulation of electrostatic clamp 400 may include absorbing unwanted heat by the thermally conditioned fluid from electrostatic clamp 400. This unwanted heat may be transferred through clamping surface 406a and/or burls to electrostatic clamp 400 from object 407 in a clamped state.

In an example of this embodiment, object 407 may be a patterning device and the unwanted heat may be transferred to the patterning device from, for example, the illumination system, and/or other systems of lithographic apparatus 100 during their operation. Presence of unwanted heat in the patterning device may cause deformation of the patterning device that may lead to errors in the patterns transferred from the patterning device to the substrate. To prevent this deformation, the temperature of the patterning device may be maintained at substantially room temperature (approximately 22 degrees Celsius) or any other defined operating temperature, according to various embodiments. This temperature regulation of the patterning device may include transferring of heat from the patterning device (e.g., through clamping surface 406a, burls 416) to electrostatic clamp 400, as discussed above, and thereby reducing or eliminating the heat-induced deformation of the patterning device.

FIG. 5 illustrates a schematic of a cross-sectional view of an electrostatic clamp 500 coupled to a chuck 520, according to an embodiment. Electrostatic clamp 500 and chuck 520 may be implemented as a part of lithographic apparatus 100, according to an example of this embodiment. Chuck 520 may be configured to couple electrostatic clamp 500 to substrate table WT and/or support structure MA in an example embodiment. Electrostatic clamp 500 may be similar to electrostatic clamp 400 in structure and function except for the differences described below. Fluid channels 522 may be configured to run parallel to surface 520a and to carry a thermally conditioned fluid as fluid channels 416. A fluid conditioning system 518 coupled to chuck 520 may be configured to condition the thermally conditioned fluid to a desired temperature before entering fluid channels 522 and to circulate it through electrostatic clamp 500 and chuck 504. The circulating thermally conditioned fluid may help to regulate temperature of electrostatic clamp 500 and chuck 520 to a desired temperature. Temperature regulation of electrostatic clamp 500 and chuck 520 may include absorbing unwanted heat by the thermally conditioned fluid from electrostatic clamp 500 and chuck 520. The unwanted heat in electrostatic clamp 500 may be transferred from object 407, as described above and the unwanted heat in chuck 520 may be transferred from electrostatic clamp 500 and/or other parts of lithographic apparatus 100 coupled to chuck 520.

### An Example Method for Manufacturing an Electrostatic Clamp

FIGS. 6A-N illustrate cross-sectional views of electrostatic clamp 400 (as shown in FIG. 4) at select stages of its manufacturing process, according to an embodiment.

FIGS. 6A-B illustrate cross-sectional views of a partially formed electrostatic clamp 400 during formation of fluid channels 416 (as described above with reference to FIGS. 4-5), according to an embodiment. The formation of fluid channels 416 may include formation of trenches 630 on surface 402a of first layer 402 (as shown in FIG. 6A) and formation of a stacked structure 632 (as shown in FIG. 6B).

The formation of trenches 630 may include polishing, machining, and etching of surface 402a, according to an embodiment. The polishing of surface 402a may be performed using any suitable polishing process, such as, but not limited to, cerium oxide slurry polishing process to obtain a smooth surface having a root mean square (RMS) roughness of about 0.5 mm or lower. Following the polishing, surface 402a may be machined using standard glass machining techniques and/or patterned and etched using standard photolithography and glass etching process to form trenches 630 (as shown in FIG. 6A). It should be noted that the rectangular cross-sectional shape of trenches 630, as illustrated in FIG. 6A, is for illustrative purposes, and is not limiting. Trenches 630 may have other cross-sectional shapes (e.g., conical, trapezoidal), according to various embodiments, without departing from the spirit and scope of the present disclosure. Subsequent to the machining, an acid etch may be performed on the machined surface 402a using, for example, an acid mixture comprising hydrofluoric acid. The acid etch may remove few microns (e.g., about 5 microns) of layer 402 material from machined surface 402a. This removal of material from machined surface 402a may help to relieve stress in layer 402 that may be induced from the machining process. The stress may be due to small deformations on surface 402a that developed from the physical force of machining.

According to an embodiment, the acid etch process may be followed by the coupling of layer 402 to second layer 404 to form stacked structure 632, as illustrated in FIG. 6B. The coupling process may include polishing of surface 604b, cleaning of surfaces 402a and 404b followed by direct bonding of first layer 402 to second layer 404. Surface 404b may be polished to a root mean square (RMS) roughness of about 0.5 mm or lower using any suitable polishing process, such as, but not limited to, cerium oxide slurry polishing process. Surface 402A may be grinded and polished after the machining of trenches 630. Subsequently, first layer 402 may be direct bonded to second layer 404 to form a stacked structure 632 by pressing surface 402a against surface 404b under a pressure suitable for the layer materials used. Optionally, the stacked structure 632 may be annealed at a temperature in the range of about 350-900 degrees Celsius (°C) to strengthen the direct bonded interface between first layer 402 and second layer 404. In some aspects, the bonding method described later herein may be applied.

Direct bonding herein may refer to an optical contact bonding that is a bonding between substantially defect free and highly polished surfaces (e.g., surfaces 402a and 404b) without the use of any bonding material, such as epoxy or any other adhesive material, according to an embodiment. Optical contact bonding may result from attractive intermolecular electrostatic interactions, such as Van der Waals forces between bonding surfaces (e.g., surfaces 402a and 404b). Annealing the optical contact bond (as described above) may transform, for example, the Van der Waals bonds between the bonding surfaces into stronger covalent bonds, and thereby strengthen the optical contact bonded structure.

The formation of fluid channels 416 may be followed by thinning down of layer 404 to about 2 mm, according to an embodiment. Surface 404b may be polished using any suitable polishing and/or grinding technique to thin down second layer 404. Alternatively, the thinning down process of second layer 404 may be performed prior to formation of fluid channel 416 by polishing surface 404a and/or surface 404b.

FIGS. 6C-D illustrate cross-sectional views of a partially formed electrostatic clamp 400 during formation of electrically conductive regions 410, according to an embodiment. The formation of electrically conductive regions 410 may include deposition of, for example, one or more metal layers 610 on third layer 406, as shown in FIG. 6C. This metal deposition may be followed by a patterning and an etching process to define electrically conductive regions 410, as shown in FIG. 6D. The deposition of layer 610 may be performed using any conventional methods suitable for metals such as, but not limited to, sputtering, thermal evaporation, atomic layer deposition (ALD), or chemical vapor deposition (CVD). The patterning process may be performed by conventional photolithography process and the etching process may be performed by wet etch methods or dry etch methods such as, but not limited to, reactive ion etching (RIE).

FIGS. 6E-F illustrate cross-sectional views of a partially formed electrostatic clamp 400 during formation of insulating regions 412, according to an embodiment. Electrically conductive regions 410 may be covered with photoresist and a dielectric may be deposited the insulating regions may be deposited coplanar with the top of the electrically conductive regions 410. In some aspects, the photoresist is subsequently removed using a suitable organic solvent or digested off using a strong oxidant. In some embodiments, the insulating regions may be formed using other techniques known in the art.

FIGS. 6G-H illustrate cross-sectional views of a partially formed electrostatic clamp 400 during bonding of composite layer 408 to stacked structure 632 (as described with reference to FIG. 6B), according to an embodiment. This bonding process may include depositing intermediate layer 414 on composite layer 408, as shown in FIG. 6G. The intermediate layer 414 may help to provide a bonding surface 414a to composite layer 408 compatible for direct bonding with surface 404a. The intermediate layer 414 may be deposited using any suitable methods for depositing, for example, silicon oxide, such as CVD process. The bonding process may further include pressing the combined structure of FIG. 6G against stacked structure 632 to bond surface 414a to surface 404a as shown in FIG. 6H. To strengthen the bonded interface between surface 414a and surface 304a, the bonded structure may be annealed at a temperature in the range of about 350-900 °C.

Optionally, the bonding process may be followed by a thinning down process of third layer 406 to a vertical dimension in the range of about 50-200 microns, according to an embodiment. Surface 406a may be polished using any suitable polishing and/or grinding technique to thin down layer 406. Alternatively, the thinning down process of third layer 406 may be performed prior to formation of composite layer 408 by polishing surface 406a and/or surface 406b.

FIG. 6I-J illustrate cross-sectional views of an electrostatic clamp 400 during formation of burls 405 on clamping surface 406a, according to an embodiment. Burls 405 may be formed by depositing, for example, a polymeric layer 605 as shown in FIG. 6I. This deposition may be followed by patterning and etching polymeric layer 605 to define burls 405, as shown in FIG. 6J. The patterning and etching process may be performed by methods as mentioned above. It should be noted that the rectangular cross-sectional shape of burls 405 is for illustrative purposes, and is not limiting. Burls 405 may have other cross-sectional shapes (e.g., spherical, conical, trapezoidal), according to various embodiments.

In an alternative approach, composite layer 408 and intermediate layer 414 may be formed on surface 404a of stacked structure 632 as illustrated in FIG. 6K, according to an embodiment. Third layer 406 may be direct bonded to intermediate layer 414 and thinned down to a vertical dimension in the range of about 50-200 microns, as shown in FIG. 6L. The direct bonding and the thinning down may be performed by methods as mentioned above.

As illustrated in FIG. 6M, in another alternative approach, a first portion 608a and a second portion 608b of composite layer 408 may be formed on surface 406b and surface 404a, respectively, according to an embodiment. First portion 608a and second portion 608b may be thermally fused together to form composite layer 408, as shown in FIG. 6N.

### An Example Method for Coupling an Electrostatic Clamp to a Chuck

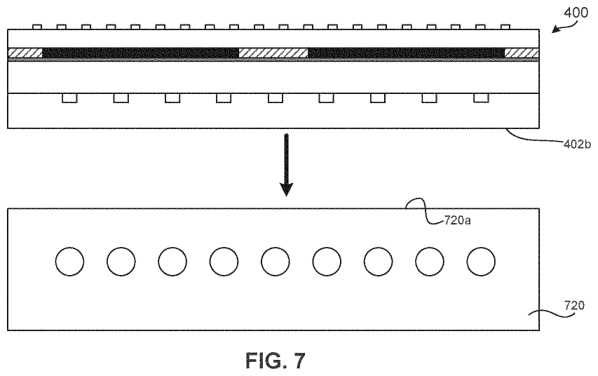

FIG. 7 illustrates a cross-sectional view of electrostatic clamp 400 during coupling of electrostatic clamp 400 to a chuck 720. Chuck 720 may be similar to chuck 520 in structure and function, as described above with reference to FIG. 5. In an embodiment, the coupling process may include polishing and cleaning of surfaces 402b and 720a followed by direct bonding of these surfaces. Surfaces 402b and 720a may be polished to a root mean square (RMS) roughness of about 0.5 mm or lower using any suitable polishing process, such as, but not limited to, cerium oxide slurry polishing process. Subsequently, surfaces 402b and 720a may be pressed together to form a direct bond between surfaces 402b and 720a. As would be appreciated by those skilled in the relevant art(s), other types of bonding or coupling may be used for coupling of electrostatic clamp 400 to chuck 720.

### Bonding Profile

With reference to FIGS. 4, 6H, and 6M, one or more layers described previously herein may be treated by a heat treatment. The heat treatment may be used to form a durable connection between layers of the stacked structure may also be referred to as bonding. In some aspects, first layer 402 and second layer 404 may be subjected to the heat treatment to bond surfaces 402a and surface 404b of FIG. 4. In addition aspect, the heat treatment may be applied to structure 632 to bond surface 414a to surface 404a of FIG. 6H, to third layer 406 to bond with intermediate layer 414, and first portion 608a and second portion 608b of FIG. 6M.

A structure (i.e., one or more layers) may be heated in a bonding oven. The structure may be heated up to a holding temperature. In some aspects, the structure may be heated to the holding temperature at a heating rate. In some aspects, the holding temperature may be greater than about 350 °C. In some aspects, the holding temperature may be from about 350 °C to about 900 °C, from about 700 °C to about 900 °C, from about 750 °C to about 850 °C, from about 780 °C to about 820 °C, about 805 °C, about 810 °C, or about 815 °C. In some aspects, the heating rate may be from about 2 °C/hour to about 60 °C/hour, from about 10 °C/hour to about 55 °C/hour, less than 60 °C/hour, or less than 55 °C/hour.

In some embodiments, the structure may be heated to an intermediate temperature (lower than the holding temperature) at a first heating rate, then to the holding temperature at a second heating rate. In some aspects, the first heating rate is greater than the second heating rate.

In some aspects, the first heating rate may be from about 20 °C/hour to about 80 °C/hour, from about 30 °C to about 70 °C/hour, from about 40 °C/hour to about 60 °C/hour, or from about 45 °C/hour to about 55 °C/hour. In some embodiments, the second heating rate is from about 1 °C/hour to about 5 °C/hour or from about 2 °C/hour to about 4 °C/hour. In some aspects, the intermediate temperature may be from about 5 °C to about 20 °C lower than the holding temperature. For example, the holding temperature may be from about 805 °C to about 815 °C and the intermediate temperature may be from about 795 °C to about 805 °C.

In some embodiments, the structure may be maintained at the holding temperature for a holding time period. In some aspects, the holding time period may be at least 5 hours, at least 10 hours, at least 15 hours, or at least 20 hours. In some aspects, the holding time period may be from about 5 hours to about 30 hours, from about 10 hours to about 25 hours, from about 15 hours to about 20 hours, from about 20 hours to about 30 hours, or from about 22 hours to about 26 hours.

The structure may be cooled after the holding time has elapsed. The temperature may be reduced from the holding temperature to a room temperature. In some aspects, the structure may be cooled at different cooling rates until a desired temperature or the room temperature is reached. That is, the temperature of the structure may be reduced at the different cooling rates. For example, one or more cooling rates may be used. In some aspects, the structure is cooled at a first cooling rate until the desired temperature is reached. Then, the cooling can take place at any cooling rate until the room temperature is reached (i.e., uncontrolled).

In some embodiments, the first cooling rate may be from about 5 °C/hour to about 20 °C/hour, from about 7 °C/hour to about 15 °C/hour, or about 10 °C/hour. In some aspects, the desired temperature may be about 100 °C lower than the holding temperature. For example, the desired temperature may be about 700 °C when the holding temperature is about 810 °C. In some aspects, the desired temperature may be equal to about 700 °C, about 600 °C, about 500 °C, about 400 °C, or about 300 °C.

In some embodiments, the structure may be cooled at a first cooling rate until a first desired temperature is reached, then at a second cooling rate until a second desired temperature is reached. In some aspects, the second cooling rate may be greater than the first cooling rate. For example, the first cooling rate may be from about 5 °C/hour to about 15 °C/hour and the second cooling rate may be from about 40 °C/hour to about 60 °C/hour. In some embodiments, the first desired temperature may be about 650 °C to about 750 °C and the second desired temperature may be about 550 °C to about 450 °C. Once the second desired temperature is reached, the cooling may be continued at an uncontrolled rate until the room temperature is reached.

In some embodiments, the structure may be cooled at a first cooling rate until a first desired temperature is reached, then at a second cooling rate until a second desired temperature is reached. Then, the structure may be cooled at a third cooling rate until a third desired temperature is reached. The structure may be cooled without restrictions on the cooling rate until the room temperature is reached once the third desired temperature is reached. In some aspects, the second cooling rate may be greater than the first cooling rate and the third cooling rate may be greater than the second cooling rate. For example, the first cooling rate may be from about 5 °C/hour to about 15 °C/hour and the second cooling rate may be from about 40 °C/hour to about 60 °C/hour. In some aspects, the third cooling rate may be from about 80 °C/hour to about 120 °C/hour. In some embodiments, the first desired temperature may be about 650 °C to about 750 °C and the second desired temperature may be about 550 °C to about 450 °C. In some aspects, the third desired temperature may be about 350 °C to about 250 °C.

In some embodiments, the structure may be cooled at a controlled rate for a first period. In some aspects, the first period may be at least about 10 hours, at least about 15 hours, or at least about 20 hours.

In some embodiments, the cooling rates, the holding temperature, and the holding period time may be selected based on the material properties of the layers of the structure. For example, measurements may be carried to determine one or more properties of the material and a cooling rate may be selected based on the measured properties. As described previously herein the layers of the structure (clamp) may be manufactured out of one or more dielectric materials configured to support an electrostatic field during operation of the clamp 400. The dielectric materials may have ultra-low thermal expansion coefficients that may be equal to zero or substantially zero. In some aspects, the bonding profile described above has minimal effect on the expansion coefficients because it may be adjusted based on the materials used.

### Example Steps for Manufacturing an Electrostatic Clamp

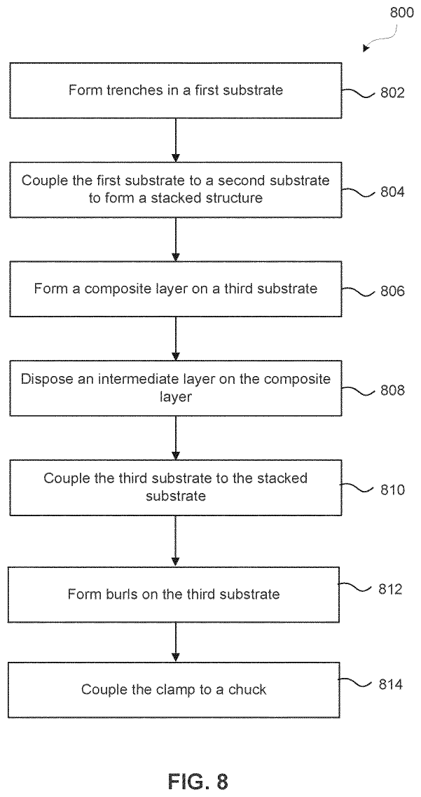

FIG. 8 illustrates a flowchart for manufacturing electrostatic clamp 400 and coupling electrostatic clamp 400 to a chuck, according to an embodiment. Solely for illustrative purposes, the steps illustrated in FIG. 8 will be described with reference to example fabrication process illustrated in FIGS. 6A-6N and 7. Steps can be performed in a different order or not performed depending on specific applications.

In step 802, trenches are formed on a first layer. For example, trenches such as trenches 630 may be formed a first layer such as first layer 402, as illustrated in FIG. 6A. Trenches 630 may be formed using standard glass machining techniques.

In step 804, the first layer is coupled to a second layer to form a stacked structure. For example, a second layer such as second layer 404 may be coupled to first layer 402 to form a stacked structure similar to stacked structure 632, as illustrated in FIG. 6B. The coupling process may include direct bonding of surfaces 402a and 404b. Direct bonding may be performed by pressing surface 402a against surface 404b under a pressure suitable for the layer materials used. The stacked structure 632 may be annealed at a temperature in the range of about 350-900 degrees Celsius.

In step 806, a composite layer is formed on a third layer. For example, a composite layer similar to composite layer 408 may be formed on third layer 406, as illustrated in FIGS. 6C-F. Composite layer 408 may be formed by deposition, patterning, and etching of a metal layer such as metal layer 610 on third layer 406 followed by deposition, patterning, and etching of a dielectric layer such as dielectric layer 612. The deposition of metal layer 610 may be performed using, for example, sputtering, thermal evaporation, atomic layer deposition (ALD), or chemical vapor deposition (CVD). The deposition of dielectric layer 612 may be performed using, for example, CVD process, magnetron sputtering, thermal evaporation, or e-beam evaporation.

In step 808, an intermediate layer is formed on the composite layer. For example, an intermediate layer similar to intermediate layer 414 may be formed on composite layer 408, as illustrated in FIG. 6G. Intermediate layer 414 may be deposited using, for example, CVD process.

In step 810, the third layer is coupled to the stacked structure to form an electrostatic clamp. For example, third layer 406 may be coupled to stacked structure 632 by direct bonding intermediate layer 414 to surface 404a of stacked structure, as illustrated in FIG. 6H.

In optional step 812, burls are formed on clamping surface of the clamp. For example, burls such as burls 405 may be formed on clamping surface such as clamping surface 406a of third layer 406, as illustrated in FIGS. 6I-J. Burls 405 may be formed by deposition, patterning, and etching of a polymeric layer 605.

In optional step 814, the electrostatic clamp is coupled to a chuck. For example, electrostatic clamp 400 may be coupled to a chuck similar to chuck 720, as illustrated in FIG. 7. The coupling may be performed by direct bonding surface 402b of clamp 400 to surface 720a of chuck 720.

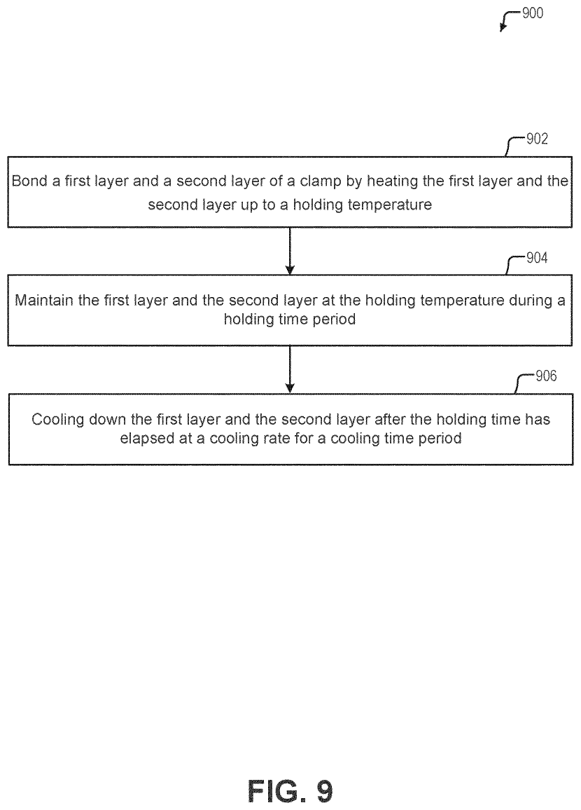

FIG. 9 illustrates a flowchart for a bonding method 900, according to an embodiment.

In step 902, a first layer and a second layer of a structure (e.g., clamp) are heated up to a holding temperature (e.g., first layer 402 and second layer 404 to bond surfaces 402a and 404b of FIG. 4, first portion 608a and second portion 608b of FIG. 6M). In some aspects, the holding temperature is at least 700 °C.

In step 904, the first layer and the second layer are maintained at the holding temperature during a holding time period. In some aspects, the holding time period is at least 5 hours.

In step 906, the first layer and the second layer are cooled down after the holding time has elapsed at a cooling rate for a cooling time period. The cooling rate may be of a maximum of 20 °C/hour for the cooling time period. In some aspects, the cooling time period is at least 10 hours. In some aspects, the first layer and the second layer are cooled to a temperature of 700 °C or less at the cooling rate.

### Example Computing System

Aspects of the disclosure can be implemented in hardware, firmware, software, or any combination thereof. For example, the design of one or more of the holding temperature, the holding time period, the cooling time period, and/or the cooling rate may be implemented using hardware, firmware, software, or any combination thereof.

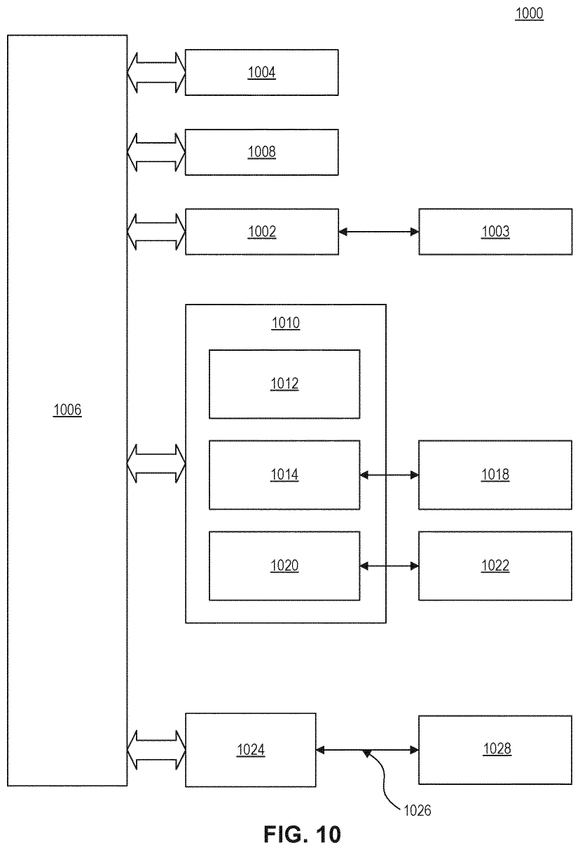

FIG. 10 shows a computer system 1000, according to some embodiments. Various embodiments and components therein can be implemented, for example, using computer system 1000 or any other well-known computer systems. For example, the method steps of FIG. 9 may be implemented via computer system 1000.

In some embodiments, computer system 1000 may comprise one or more processors (also called central processing units, or CPUs), such as a processor 1004. Processor 1004 may be connected to a communication infrastructure or bus 1006.

In some embodiments, one or more processors 1004 may each be a graphics processing unit (GPU). In an embodiment, a GPU is a processor that is a specialized electronic circuit designed to process mathematically intensive applications. The GPU may have a parallel structure that is efficient for parallel processing of large blocks of data, such as mathematically intensive data common to computer graphics applications, images, videos, etc.

In some embodiments, computer system 1000 may further comprise user input/output device(s) 1003, such as monitors, keyboards, pointing devices, etc., that communicate with communication infrastructure 1006 through user input/output interface(s) 1002. Computer system 1000 may further comprise a main or primary memory 1008, such as random access memory (RAM). Main memory 1008 may comprise one or more levels of cache. Main memory 1008 has stored therein control logic (i.e., computer software) and/or data.

In some embodiments, computer system 1000 may further comprise one or more secondary storage devices or memory 1010. Secondary memory 1010 may comprise, for example, a hard disk drive 1012 and/or a removable storage device or drive 1014. Removable storage drive 1014 may be a floppy disk drive, a magnetic tape drive, a compact disk drive, an optical storage device, tape backup device, and/or any other storage device/drive. removable storage drive 1014 may interact with a removable storage unit 1018. Removable storage unit 1018 may comprise a computer usable or readable storage device having stored thereon computer software (control logic) and/or data.

Removable storage unit 1018 may be a floppy disk, magnetic tape, compact disk, DVD, optical storage disk, and/any other computer data storage device. Removable storage drive 1014 reads from and/or writes to removable storage unit 1018 in a well-known manner.

In some embodiments, secondary memory 1010 may comprise other means, instrumentalities or other approaches for allowing computer programs and/or other instructions and/or data to be accessed by computer system 1000. Such means, instrumentalities or other approaches may comprise, for example, a removable storage unit 1022 and an interface 1020. Examples of the removable storage unit 1022 and the interface 1020 may comprise a program cartridge and cartridge interface (such as that found in video game devices), a removable memory chip (such as an EPROM or PROM) and associated socket, a memory stick and USB port, a memory card and associated memory card slot, and/or any other removable storage unit and associated interface.

In some embodiments, computer system 1000 may further comprise a communication or network interface 1024. Communication interface 1024 enables computer system 1000 to communicate and interact with any combination of remote devices, remote networks, remote entities, etc. (individually and collectively referenced by reference number 1028). For example, communication interface 1024 may allow computer system 1000 to communicate with remote devices 1028 over communications path 1026, which may be wired and/or wireless, and which may comprise any combination of LANs, WANs, the Internet, etc. Control logic and/or data may be transmitted to and from computer system 1000 via communications path 1026.

In some embodiments, a non-transitory, tangible apparatus or article of manufacture comprising a non-transitory, tangible computer useable or readable medium having control logic (software) stored thereon is also referred to herein as a computer program product or program storage device. This includes, but is not limited to, computer system 1000, main memory 1008, secondary memory 1010, and removable storage units 1018 and 1022, as well as tangible articles of manufacture embodying any combination of the foregoing. Such control logic, when executed by one or more data processing devices (such as computer system 1000), causes such data processing devices to operate as described herein.

Based on the teachings contained in this disclosure, it will be apparent to those skilled in the relevant art(s) how to make and use embodiments of this disclosure using data processing devices, computer systems and/or computer architectures other than that shown in FIG. 9. In particular, embodiments may operate with software, hardware, and/or operating system implementations other than those described herein.

The embodiments may further be described using the following clauses:
1. A method comprising:
   bonding a first layer and a second layer of a clamp by heating the first layer and the second layer up to a holding temperature of at least 700 °C;
   maintaining the first layer and the second layer at the holding temperature during a holding time period; and
   cooling down the first layer and the second layer after the holding time has elapsed at a cooling rate of a maximum of 20 °C/hour for a cooling time period.
2. The method of clause 1, wherein the holding temperature is from about 700 °C to about 900 °C.
3. The method of clause 2, wherein the holding temperature is from about 750 °C to about 850 °C.
4. The method of clause 3, wherein the holding temperature is about 810 °C.
5. The method of clause 1, wherein the holding time period is at least 5 hours.
6. The method of clause 5, wherein the holding time period is from about 5 hours to about 30 hours.
7. The method of clause 1, further comprising:
   heating the first layer and the second layer to a first temperature lower than the holding temperature at a first rate and to the holding temperature at a second rate, wherein the first rate is higher than the second rate.
8. The method of clause 1, wherein the first layer and the second layer are heated at a rate from about 2 °C/hour to about 60 °C/hour.
9. The method of clause 1, further comprising:
   cooling down the first layer and the second layer at another rate for another cooling period subsequent to the cooling period, wherein the rate is lower than the another rate.
10. The method of clause 1, wherein the cooling rate is from about 5 °C/hour to about 20 °C/hour.
11. The method of clause 1, wherein the cooling time period is at least 10 hours.
12. The method of clause 1, wherein the first layer and the second layer are cooled to a temperature of 700 °C or less at the cooling rate.
13. A lithographic apparatus comprising:
   a chuck; and
   an electrostatic clamp, coupled to the chuck, configured to releasably hold a patterning device, the electrostatic clamp comprising:
      a first layer and a second layer, wherein the first layer and the second layer are bonded together using a heat treatment, and wherein the heat treatment comprises heating the first layer and the second layer up to a holding temperature of a least 700 °C, maintaining the first layer and the second layer at the holding temperature during a holding time period, and cooling down the first layer and the second layer after the holding time period has elapsed at a cooling rate of a maximum of 20 °C/hour for a cooling time period.
14. The lithographic apparatus of clause 13, wherein the holding temperature is from about 700 °C to about 900 °C.
15. The lithographic apparatus of clause 14, wherein the holding temperature is from about 750 °C to about 850 °C.
16. The lithographic apparatus of clause 13, wherein the holding time period is at least 5 hours.
17. The lithographic apparatus of clause 16, wherein the holding time period is from about 5 hours to about 30 hours.
18. The lithographic apparatus of clause 13, wherein the cooling rate is from about 5 °C/hour to about 20 °C/hour.
19. The lithographic apparatus of clause 13, wherein the cooling time period is at least 10 hours.
20. A clamp:
   a first layer and a second layer,
   wherein the first layer and the second layer are bonded together using a heat treatment; and
   wherein the heat treatment comprises heating the first layer and the second layer up to a holding temperature of a least 700 °C, maintaining the first layer and the second layer at the holding temperature during a holding time period, and cooling down the first layer and the second layer after the holding time has elapsed at a cooling rate of a maximum of 20 °C/hour for a cooling time period.

Although specific reference may be made in this text to the use an electrostatic clamp in lithographic apparatus, it should be understood that the electrostatic clamp described herein may have other applications, such as for use in mask inspection apparatus, wafer inspection apparatus, aerial image metrology apparatus and more generally in any apparatus that measures or processes an object such as a wafer (or other substrate) or mask (or other patterning device) either in vacuum or in ambient (non-vacuum) conditions, such as, for example in plasma etching apparatus or deposition apparatus.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the present disclosure in the context of optical lithography, it will be appreciated that the present disclosure may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present specification is to be interpreted by those skilled in relevant art(s) in light of the teachings herein.

The terms “radiation” and “beam” as used herein encompass all types of electromagnetic radiation, including ultraviolet (UV) radiation (e.g., having a wavelength of or about 365, 355, 248, 193, 157 or 126 nm) and extreme ultraviolet (EUV) radiation (e.g., having a wavelength in the range of 5-20 nm), as well as beams of charged particles, such as ion beams or electron beams.

The term “lens”, where the context allows, may refer to any one or combination of various types of optical components, including refractive, reflective, magnetic, electromagnetic and electrostatic optical components.

The term “etch” or “etching” or “etch-back” as used herein generally describes a fabrication process of patterning a material, such that at least a portion of the material remains after the etch is completed. For example, generally the process of etching a material involves the steps of patterning a masking layer (e.g., photoresist or a hard mask) over the material, subsequently removing areas of the material that are no longer protected by the mask layer, and optionally removing remaining portions of the mask layer. Generally, the removing step is conducted using an “etchant” that has a “selectivity” that is higher to the material than to the mask layer. As such, the areas of material protected by the mask would remain after the etch process is complete. However, the above is provided for purposes of illustration, and is not limiting. In another example, etching may also refer to a process that does not use a mask, but still leaves behind at least a portion of the material after the etch process is complete.

The above description serves to distinguish the term “etching” from “removing.” In an embodiment, when etching a material, at least a portion of the material remains behind after the process is completed. In contrast, when removing a material, substantially all of the material is removed in the process. However, in other embodiments, ‘removing’ may incorporate etching.

The terms “deposit” or “dispose” as used herein describe the act of applying a layer of material to a substrate. Such terms are meant to describe any possible layer-forming technique including, but not limited to, thermal growth, sputtering, evaporation, chemical vapor deposition, epitaxial growth, atomic layer deposition, electroplating, etc.

The term “substrate” as used herein describes a material onto which subsequent material layers are added. In embodiments, the substrate itself may be patterned and materials added on top of it may also be patterned, or may remain without patterning.

The term “substantially” or “in substantial contact” as used herein generally describes elements or structures in physical substantial contact with each other with only a slight separation from each other which typically results from fabrication and/or misalignment tolerances. It should be understood that relative spatial descriptions between one or more particular features, structures, or characteristics (e.g., “vertically aligned,” “substantial contact,” etc.) used herein are for purposes of illustration only, and that practical implementations of the structures described herein may include fabrication and/or misalignment tolerances without departing from the spirit and scope of the present disclosure.

While specific embodiments of the disclosure have been described above, it will be appreciated that embodiments of the present disclosure may be practiced otherwise than as described. The descriptions are intended to be illustrative, not limiting. Thus it will be apparent to one skilled in the art that modifications may be made to the disclosure as described without departing from the scope of the claims set out below.

It is to be appreciated that the Detailed Description section, and not the Summary and Abstract sections, is intended to be used to interpret the claims. The Summary and Abstract sections may set forth one or more but not all exemplary embodiments of the present disclosure as contemplated by the inventor(s), and thus, are not intended to limit the present disclosure and the appended claims in any way.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the present disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein.

The breadth and scope of the protected subject matter should not be limited by any of the above-described exemplary embodiments, but should be defined only in accordance with the following claims and their equivalents.

1. A method comprising:
bonding a first layer and a second layer of a clamp by heating the first layer and the second layer up to a holding temperature of at least 700 °C;
maintaining the first layer and the second layer at the holding temperature during a holding time period; and
cooling down the first layer and the second layer after the holding time period has elapsed at a cooling rate of a maximum of 20 °C/hour for a cooling time period.

2. The method of claim 1, wherein the holding temperature is from about 700 °C to about 900 °C.

3. The method of claim 2, wherein the holding temperature is from about 750 °C to about 850 °C.

4. The method of claim 3, wherein the holding temperature is about 810 °C.

5. The method of claim 1, wherein the holding time period is at least 5 hours.

6. The method of claim 5, wherein the holding time period is from about 5 hours to about 30 hours.

7. The method of claim 1, further comprising heating the first layer and the second layer to a first temperature lower than the holding temperature at a first rate and from the first temperature to the holding temperature at a second rate, wherein the first rate is higher than the second rate.

8. The method of claim 1, wherein the first layer and the second layer are heated at a rate from about 2 °C/hour to about 60 °C/hour.

9. The method of claim 1, further comprising cooling down the first layer and the second layer at another rate for another cooling period subsequent to the cooling time period, wherein the cooling rate is lower than the another rate.

10. The method of claim 1, wherein the cooling rate is from about 5 °C/hour to about 20 °C/hour.

11. The method of claim 1, wherein the cooling time period is at least 10 hours.

12. The method of claim 1, wherein the first layer and the second layer are cooled to a temperature of 700 °C or less at the cooling rate.

13. A lithographic apparatus comprising:
a chuck; and
an electrostatic clamp, coupled to the chuck, configured to releasably hold a patterning device, the electrostatic clamp comprising:
a first layer and a second layer, wherein the first layer and the second layer are bonded together using a heat treatment, and wherein the heat treatment comprises heating the first layer and the second layer up to a holding temperature of a least 700 °C, maintaining the first layer and the second layer at the holding temperature during a holding time period, and cooling down the first layer and the second layer after the holding time period has elapsed at a cooling rate of a maximum of 20 °C/hour for a cooling time period.

14. The lithographic apparatus of claim 13, wherein the holding temperature is from about 700 °C to about 900 °C.

15. The lithographic apparatus of claim 14, wherein the holding temperature is from about 750 °C to about 850 °C.

16. The lithographic apparatus of claim 13, wherein the holding time period is at least 5 hours.

17. The lithographic apparatus of claim 16, wherein the holding time period is from about 5 hours to about 30 hours.

18. The lithographic apparatus of claim 13, wherein the cooling rate is from about 5 °C/hour to about 20 °C/hour.

19. The lithographic apparatus of claim 13, wherein the cooling time period is at least 10 hours.

20. A clamp comprising:
a first layer; and
a second layer,
wherein the first layer and the second layer are bonded together using a heat treatment, the heat treatment comprising heating the first layer and the second layer up to a holding temperature of a least 700 °C, maintaining the first layer and the second layer at the holding temperature during a holding time period, and cooling down the first layer and the second layer after the holding time period has elapsed at a cooling rate of a maximum of 20 °C/hour for a cooling time period.
